(19) United States
(12) Patent Application Publication
(10) Pub. No.: US 2020/0251174 A1
(43) Pub. Date: Aug. 6, 2020

(54) SEMICONDUCTOR INTEGRATED CIRCUIT WITH A NONVOLATILE SEMICONDUCTOR MEMORY DEVICE

(71) Applicants: Kabushiki Kaisha Toshiba, Tokyo (JP); Toshiba Electronic Devices & Storage Corporation, Tokyo (JP)

(72) Inventors: Nobuyuki Ishigooka, Kawasaki Kanagawa (JP); Masaki Sekimizu, Kawasaki Kanagawa (JP); Yoshihiro Yamaguchi, Kawasaki Kanagawa (JP); Katsumichi Katou, Kawasaki Kanagawa (JP); Ryouta Niwa, Kawasaki Kanagawa (JP)

(21) Appl. No.: 16/538,020

(22) Filed: Aug. 12, 2019

(30) Foreign Application Priority Data
Jan. 31, 2019 (JP) 2019-015404

(51) Int. Cl. G11C 29/44; G11C 29/42; G06F 12/02

(52) U.S. Cl. CPC G11C 29/44; G11C 29/42; G06F 2212/2024; G06F 2212/2022; G06F 12/0246

(57) ABSTRACT

According to an embodiment, a semiconductor integrated circuit includes a nonvolatile semiconductor memory device and an integral control processing device. The nonvolatile semiconductor memory device includes a memory region formed of a data storage region to store data and a flag region in which a first value is set when data writing to the data storage region starts and a second value is set when data writing to the data storage region ends, and a controller including an error code detection circuit to detect an error code. An integral control processing device integrally controls an overall. system by exchanging various kinds of signals and data with the controller.

### CROSS REFERENCE TO RELATED APPLICATION

This application is based upon and claims the benefit of priority from the prior Japanese Patent Application No. 2019-015404, filed on Jan. 31, 2019, the entire contents of which are incorporated herein by reference.

### FIELD

The embodiments described herein are a semiconductor integrated circuit with a nonvolatile semiconductor memory device.

### BACKGROUND

Recent semiconductor integrated circuits have been further systemized and highly integrated, incorporating a volatile semiconductor memory device, a nonvolatile semiconductor memory device, a plurality of integrated circuits of different operations and functions, and the like. In the semiconductor integrated circuit, there may be a case in which the power is interrupted or shut down during a data write operation to the nonvolatile semiconductor memory device. In this case, it is considerably important to determine whether the data written to the nonvolatile semiconductor memory device is available.

When special software (software to determine data matching, for example) and the like is used to execute the determination of whether the data written to the nonvolatile semiconductor memory device is available, the processing time is long, and this causes a problem that the load on the CPU is increased and accordingly cost is increased.

There have been demands for the determination of whether the data written to the nonvolatile semiconductor memory device is available to be executed in a short time with a simple circuit configuration using no special software.

### BRIEF DESCRIPTION OF THE DRAWINGS

FIG. 1 is a diagram that shows a semiconductor integrated circuit according to a first embodiment;

FIG. 2 is a flowchart that shows a data write operation according to the first embodiment;

FIG. 3 is a flowchart that shows a data read operation according to the first embodiment;

FIG. 4 is a diagram that shows a semiconductor integrated circuit of a comparative example;

FIG. 5 is a flowchart that shows a data write operation according to the comparative example;

FIG. 6 is a flowchart that shows a data read operation according to the comparative example;

FIG. 7 is a diagram that shows a semiconductor integrated circuit according to a second embodiment;

FIG. 8 is a diagram that shows an internal configuration of a data buffer according to the second embodiment;

FIG. 9 is a flowchart that shows a data write operation according to the second embodiment;

FIG. 10 is a flowchart that shows a data read operation according to the second embodiment; and

FIG. 11 is a flowchart that shows a data write operation according to a third embodiment.

### DETAILED DESCRIPTION

According to an embodiment, a semiconductor integrated circuit includes a nonvolatile semiconductor memory device and an integral control processing device. The nonvolatile semiconductor memory device includes a. memory region formed of a data storage region to store data and a flag region in which a first value is set when data writing to the data storage region starts and a second value is set when data writing to the data storage region ends, and a controller including an error code detection circuit to detect an error code. An integral control processing device integrally controls an overall system by exchanging various kinds of signals and data with the controller.

Further embodiments will be described below with reference to the drawings. in the drawings, the same reference signs indicate the same or similar portions.

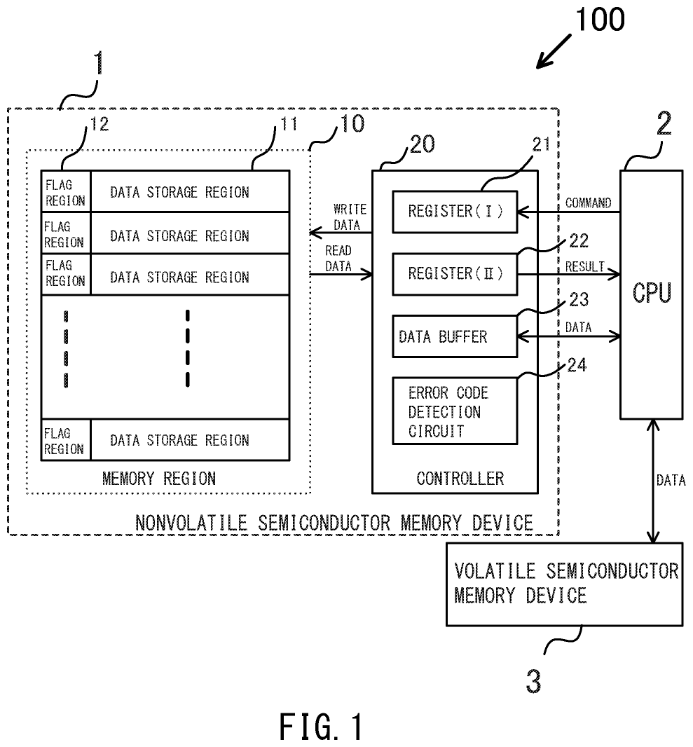

A semiconductor integrated circuit according to a first embodiment will be described with reference to the drawings. FIG. 1 is a diagram that shows the semiconductor integrated. circuit.

In the first embodiment, a memory region of a nonvolatile semiconductor memory device is provided with a data storage region and a flag region. The flag region stores “1” when writing of data to the data storage region starts and stores “0” when writing of data to the data storage region ends. Based on the information stored in the flag region, a controller determines whether the data written to the data storage region is available.

As shown in FIG. 1, a semiconductor integrated circuit 100 includes a nonvolatile semiconductor memory device 1, a CPU 2, and a volatile semiconductor memory device 3. The semiconductor integrated circuit 100 is mounted in a consumer device or an industrial device to implement a consumer system or an industrial system. The semiconductor integrated circuit 100 may be applied to an in-vehicle system, for example.

A NAND flash memory, resistive random access memory (ReRAM), magnetoresistive random access memory (MRAM), phase change random access memory (PRAM), and ferroelectric random access memory (FeRAM), for example, are used as the nonvolatile semiconductor memory device 1.

A dynamic random access memory (DRAM) and static random access memory (SRAM), for example, are used as the volatile semiconductor memory device 3.

In the semiconductor integrated circuit 100, there may be a case in which the power is interrupted or shut down during a data write operation to the nonvolatile semiconductor memory device 1.

The nonvolatile semiconductor memory device 1 includes a memory region 10 and a controller 20. The memory region 10 includes a data storage region 11 and a flag region 12. The data storage region 11 and the flag region 12 are paired with each other while including a plurality of stages (128 stages, for example). Each pair in the memory region includes the data storage region 11 having a capacity of 16 bytes, for example, and the flag region 12 having a capacity of 1 bit, for example.

Data is written to the data storage region 11 based on a command. from the central processing unit (CPU) 2. The data storage region 11 stores information that indicates whether the written data is available.

The controller 20 is provided between the memory region 10 and the CPU 2 and exchanges various kinds of signals and data with the CPU 2. The controller 20 includes a register (I) 21 (first register), a register (II) 22 (second register), a data buffer 23, and an error code detection circuit 24.

In response to the command from the CPU 2, the register (I) 21 sets a write command to the memory region 10, for example. The register (II) 22 temporarily stores a result of the writing to the memory region 10 and. transmits the written result to the CPU 2. The data buffer 23 temporarily stores the data to be written to the memory region 10 and the data read from the memory region 10. The error code detection circuit 24 detects an error code. The error code detection circuit 24 includes cyclic redundancy check (CRC), error check and correct (FCC), checksum, and parity, for example.

When the information written to the flag region 12 is “0” (second value), the controller 20 determines that the data written to the data storage region 11 is available, and when the information written to the flag region 12 is “1” (first value), the controller 20 determines that the data written to the data storage region 11 is unavailable. Details will be described later.

The CPU 2 is a processing device that integrally controls the overall system including the semiconductor integrated circuit 100. Although the CPU 2 is used as an integral control processing device in the first embodiment, it is not necessarily limited to the above case. A processor, micro processing unit (MPU), and the like may be used instead of the CPU 2.

The volatile semiconductor memory device 3 exchanges data with the CPU 2. Information read from the volatile semiconductor memory device 3 is written to the memory region 10 of the nonvolatile semiconductor memory device 1 through the CPU 2, for example. Information read from the memory region 10 of the nonvolatile semiconductor memory device 1 is written to the volatile semiconductor memory device 3 through the CPU 2, for example.

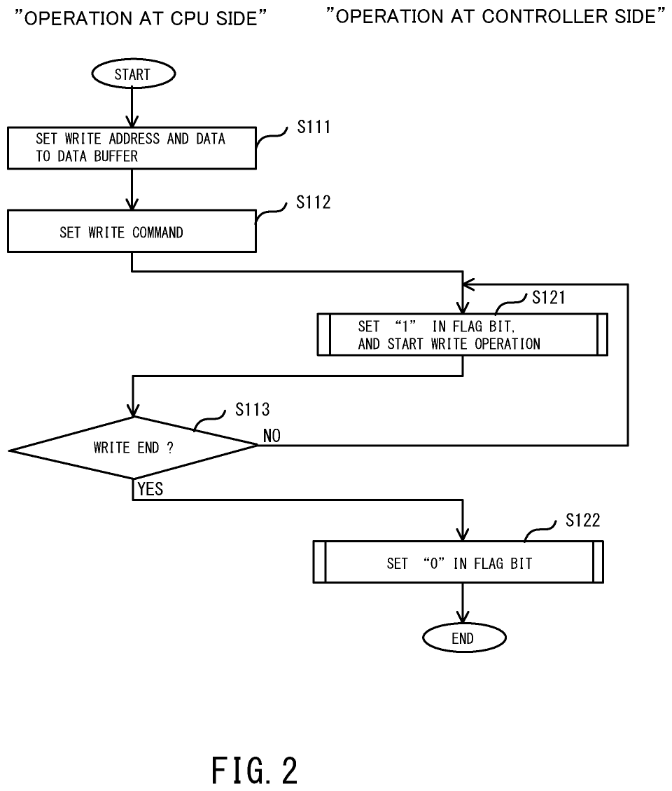

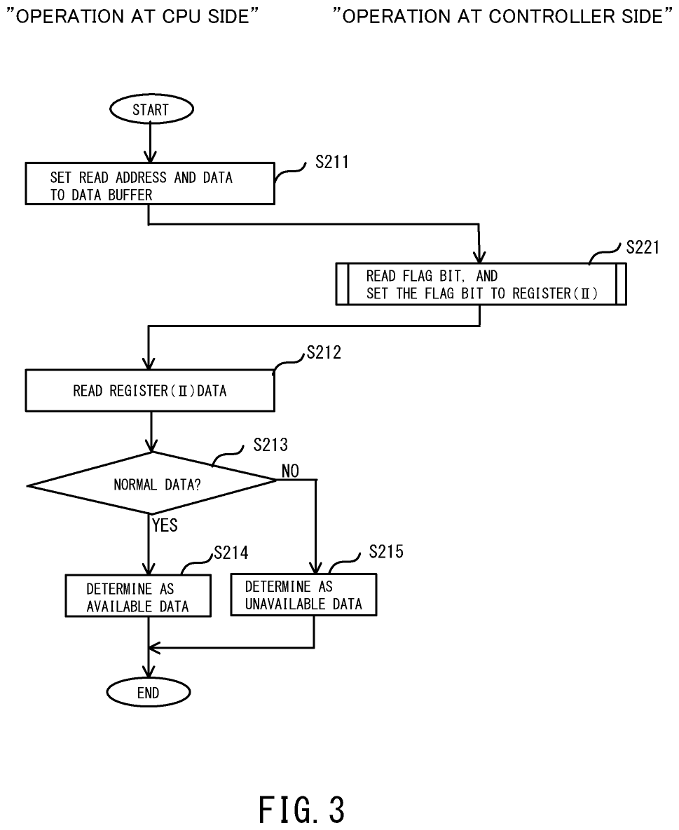

Next, operations of the semiconductor integrated circuit 100 will be described with reference to FIGS. 2 and 3. FIG. 2 is a flowchart that shows a data write operation. FIG. 3 is a flowchart that shows a data read operation. In FIGS. 2 and 3, operations at a CPU side are shown on the left while operations at a controller side are shown on the right.

As shown in FIG. 2, in the data writing, the CPU 2 sets a write address and data to the data buffer 23 (step S111). Next, the CPU 2 sets a write command to the register (I) 21 (step S112).

Subsequently, once receiving a write start command from the CPU 2, the controller 20 sets “1” (first value) in a flag bit of the flag region 12 corresponding to the data storage region 11 to which data is to be written and starts writing of the data to the data storage region 11 (step S121).

Next, the CPU 2 determines whether writing to the memory region 10 ends (step S113). When the writing to the memory region 10 does not end yet, the information in the bit of the flag region 12 remains as “1.” When the writing to the memory region 10 ends and the controller 20 receives a writing end request from the CPU 2, the controller 20 sets “0” (second value) in the bit of the flag region 12 (step S122).

As shown in FIG. 3, in the data read operation, the CPU 2 sets a read address and data to the data buffer 23 (step S211).

Next, the controller 20 reads the information in the flag bit of the flag region 12 and sets the information to the register (II) 22 (step S221). Subsequently, the CPU 2 reads the data. from the register 22 (step S212).

Next, the CPU 2 determines whether the read information is normal data (step S213). When the information in the bit of the flag region 12 is “0,” the CPU 2 determines that the read data is available (step S214). When the information in the flag bit of the flag region 12 is “1,” the CPU 2 determines that the read data is unavailable (step S215).

Based on the above-described processing flow, it can be seen that the information in the flag bit of the flag region 12 remains as “1” when the data write operation is interrupted in the middle of the process by interruption or shut-down of the power, for example. In the data reading, the controller 20 sets the address and refers to the flag bit of the register (II) 22. When the referred result is “0,” it is determined that the data in the data storage region 11 corresponding to the flag region 12 including the flag bit of “0” is available. When the referred. result is “1,” it is determined that the data writing ends abnormally, and thus it is possible to determine that the data in the data. storage region 11 corresponding to the flag region 12 with the flag bit information of “1” is unavailable.

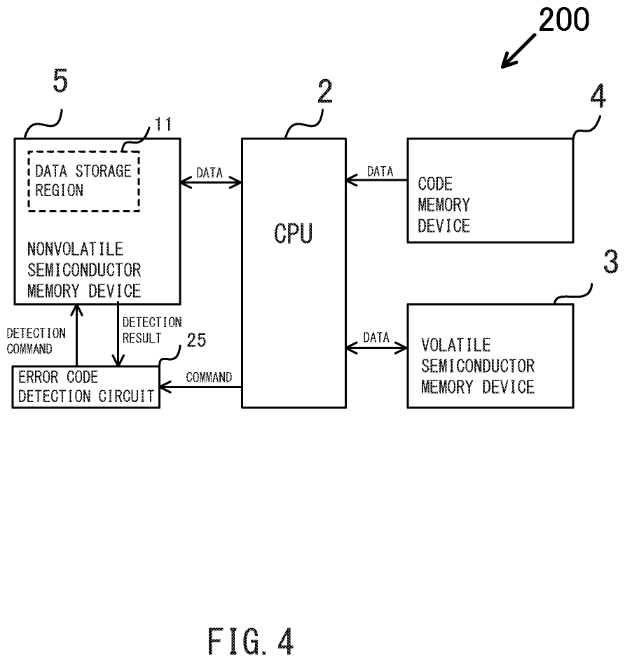

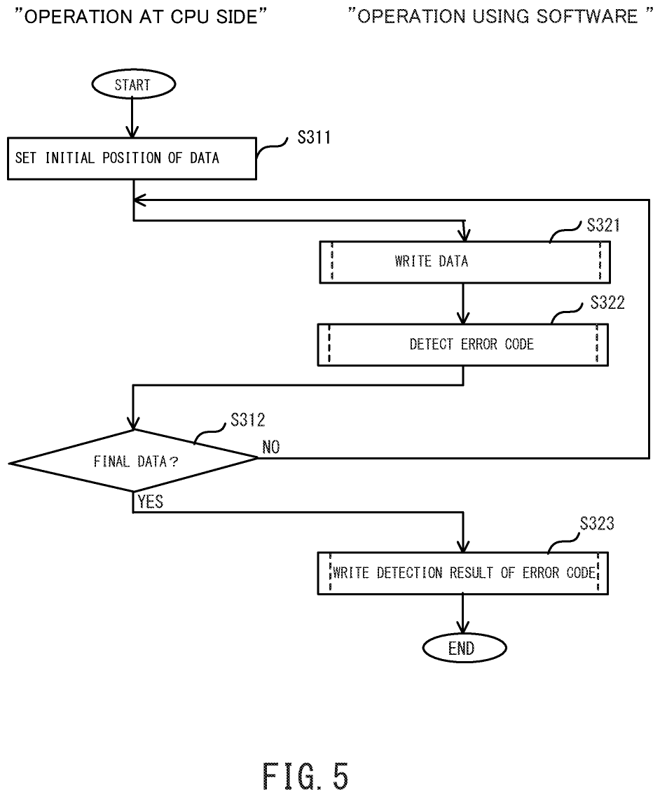

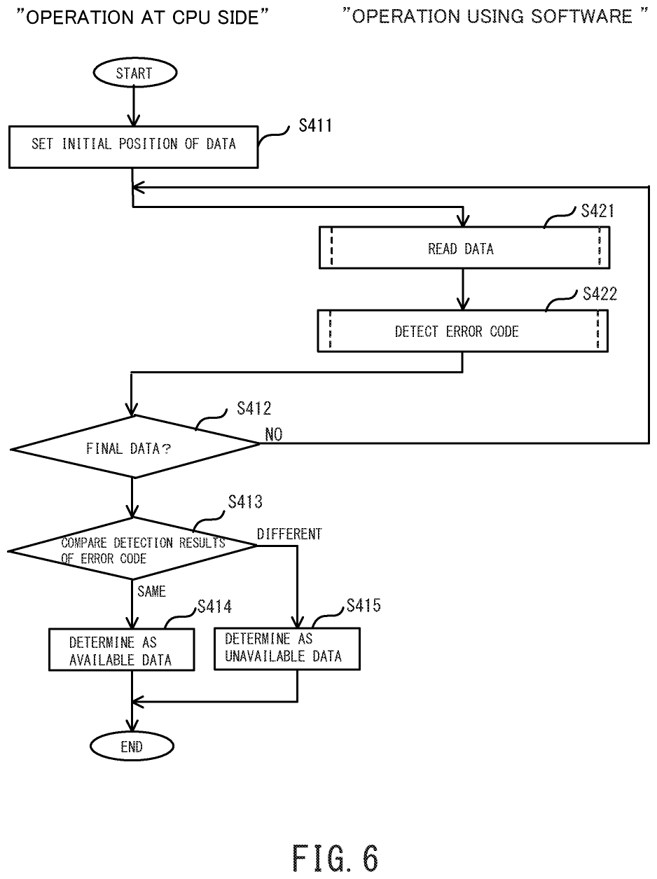

A semiconductor integrated circuit of a comparative example will be described with reference to FIGS. 4 to 6. FIG. 4 is a diagram that shows the semiconductor integrated circuit of the comparative example. FIG. 5 is a flowchart that shows a data write operation of the comparative example. FIG. 6 is a flowchart that shows a data read operation of the comparative example. In FIGS. 5 and 6, operations at a CPU side are shown on the left while operations using software are shown on the right.

As shown in FIG. 4, a semiconductor integrated circuit 200 of the comparative example includes the CPU 2, the volatile semiconductor memory device 3, a code memory device 4, a nonvolatile semiconductor memory device 5, and an error code detection circuit 25. In the semiconductor integrated circuit 200 of the comparative example, the determination of whether the written data is available is made using the software.

In the semiconductor integrated circuit 200 of the comparative example, a description of a portion different from the semiconductor integrated circuit 100 of the first embodiment is given, and a description of the same portion is omitted.

The NAND flash memory, ReRAM, MRAM, PRAM, and FeRAM, for example, are used as the nonvolatile semiconductor memory device 5.

The error code detection circuit 25 detects an error and includes the cyclic redundancy check (CRC), error check and correct (ECC), checksum, and. parity, for example.

In the semiconductor integrated circuit 200 of the comparative example, the nonvolatile semiconductor memory device 5 includes the data storage region 11 while including a plurality of stages. The CPU 2 exchanges data with the nonvolatile semiconductor memory device 5. The CPU 2 exchanges data with the volatile semiconductor memory device 3. The CPU 2 exchanges data with the code memory device 4. The CPU 2 transmits an error detection command to the error code detection circuit 25. The error code detection circuit 25 transmits an error detection command to the nonvolatile semiconductor memory device 5, receives an error detection result from the nonvolatile semiconductor memory device 5, and forwards the result to the CPU 2.

As shown in FIG. 5, in the write operation, the CPU 2 sets an initial position of data (step S311). Next, the data is written to the data storage region 11 of the nonvolatile semiconductor memory device 5 by the software processing (step S321). Subsequently, the software processing allows the error code detection circuit 25 to detect the error code of the data read by the software processing (step S322).

The CPU 2 determines whether the written data is final data (step S312). When the CPU 2 determines that the written data is not the final data, the processings of steps S321 and S322 are executed again. When the CPU 2 determines that the written data is the final data, the error code detection result is written to the code memory device 4, for example, by the software processing (step S323).

As shown in FIG. 6, in the read operation, the CPU 2 sets an initial position of data (step S411).

Next, the data is read by the software processing. In this process, a calculation result is read with the data (step S421). Subsequently, an error code of the read data is detected by the software processing (step S422).

The CPU 2 determines whether the read data is final data (step S412). When the CPU 2 determines that the read data is not the final data, the processings of steps S421 and S422 are executed again. The CPU 2 compares the error code detection result with the read data (step S413). When the comparison results are the same, the CPU 2 determines that the data is available (step S414). When the comparison results are different, the CPU 2 determines that the data is unavailable (step S415).

In the semiconductor integrated circuit of the comparative example, dedicated software is required to determine whether the error code detection result and the read data are matched. The processing time is thus longer than that of the first embodiment, and loads on the CPU are increased.

As described above, the semiconductor integrated circuit 100 of the first embodiment is provided with the nonvolatile semiconductor memory device 1, the CPU 2, and the volatile semiconductor memory device 3. The nonvolatile semiconductor memory device 1 includes the memory region 10 and the controller 20. The memory region 10 includes the data storage region 11 and the flag region 12. The controller 20 includes the register (I) 21 (first register), the register (II) 22 (second register), the data buffer 23, and the error code detection circuit 24. “1” is written, in the flag region 12, as information in the flag bit when the writing of data to the nonvolatile semiconductor memory device 1 starts, and “0” is written, in the flag region 12, as information in the flag bit when the writing of data to the nonvolatile semiconductor memory device 1 ends. The controller 20 makes determination on the information written in the flag bit. When the information in the flag bit is “0,” the controller 20 determines that the written data is available data, and when the information in the flag bit is “1,” the controller 20 determines that the written data is unavailable data.

Thus, it is possible to use a simple configuration to determine whether the data written to the nonvolatile semiconductor memory device is available. In the semiconductor integrated circuit 100 of the first embodiment, no dedicated software is required to determine whether the data written to the nonvolatile semiconductor memory device is available.

Note that, the flag region 12 includes the flag bit of 1 bit and although it is determined that the written data is available when the information in the flag bit is “0” and it is determined that the written data is unavailable when the information in the flag bit is “1” in the first embodiment, it is not necessarily limited to the above case. For example, the flag region 12 may include a flag bit of a plurality of bits. When the flag bit of a plurality of bits is used, data may be set to information other than “1” and “0.”

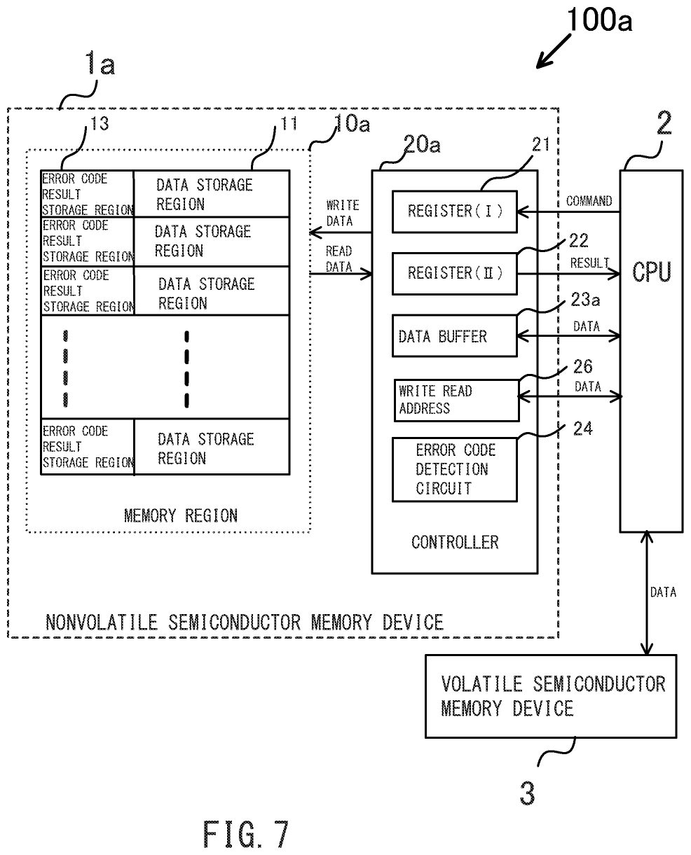

A semiconductor integrated circuit according to a second embodiment will be described with reference to the drawings. FIG. 7 is a diagram that shows a semiconductor integrated circuit.

In the second embodiment, a memory region of a nonvolatile semiconductor memory device includes data storage regions and error code result storage regions. A data buffer of a controller includes a data storage region and an error code result storage region.

Hereinafter, the same portions as the portions in the first embodiment are indicated by the same reference signs while descriptions are omitted, and only the different portions are described.

As shown in FIG. 7, a semiconductor integrated circuit 100a includes a nonvolatile semiconductor memory device la, the CPU 2, and the volatile semiconductor memory device 3. The NAND flash memory, ReRAM, MRAM, PRAM, and FeRAM, for example, are used as the nonvolatile semiconductor memory device 1a.

The nonvolatile semiconductor memory device la includes a memory region 10a. and a controller 20a. The memory region 10a includes the data storage region 11 and an error code result storage region 13. The data storage region 11 (first data storage region) and the error code result storage region 13 (first error code result storage region) are paired with each other while including a plurality of stages (128 stages, for example). Each pair in the memory region includes the data storage region 11 having a capacity of 16 bytes, for example, and the error code result storage region 13 having a capacity of 1 byte (1 byte (8 bits)), for example.

Although the capacity of the error code result storage region 13 is set to 1 byte in the embodiment, it is not necessarily limited to the above case and it can be changed as needed.

The controller 20a is provided between the memory region 10a and the CPU 2 and exchanges various kinds of signals and data with the CPU 2. The controller 20a includes the register (I) 21 (first register), the register (TI) 22 (second register), a data buffer 23a, the error code detection circuit 24, and. a write read address 26.

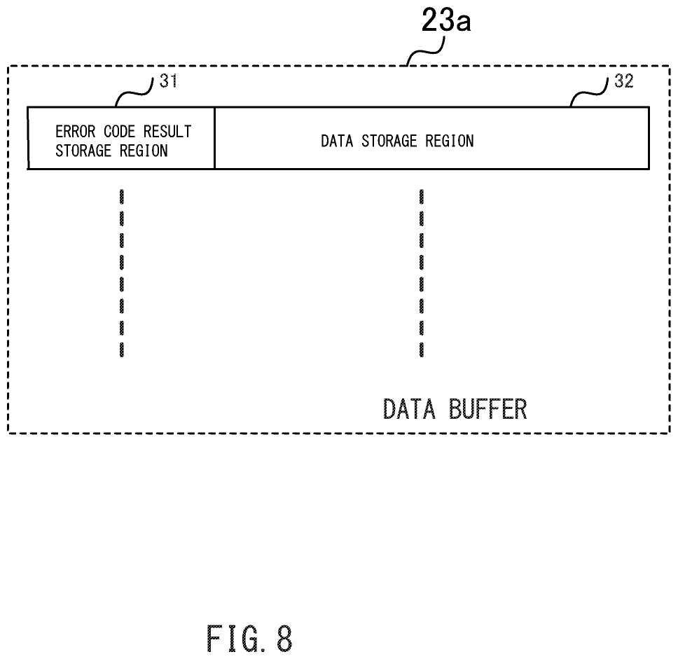

The data buffer 23a exchanges data with the CPTJ 2. As shown in FIG. 8, in the data buffer 23a, an error code result storage region 31 (second error code result storage region) having a capacity of 1 byte (1 byte (8 bits)) same as the capacity of the error code result storage region 13 (first error code result storage region) in the memory region 10a and a data storage region 32 (second data storage region) having a capacity of 16 bytes same as the capacity of the data storage region 11 (first data storage region) in the memory region 10a are paired with each other, and a plurality of stages of memory regions are provided like the memory region 10a.

The cyclic redundancy check (CRC), for example, is used for the error code detection circuit 24. and the error code detection circuit 24 detects an error code. The write read address 26 exchanges data with the CPU 2.

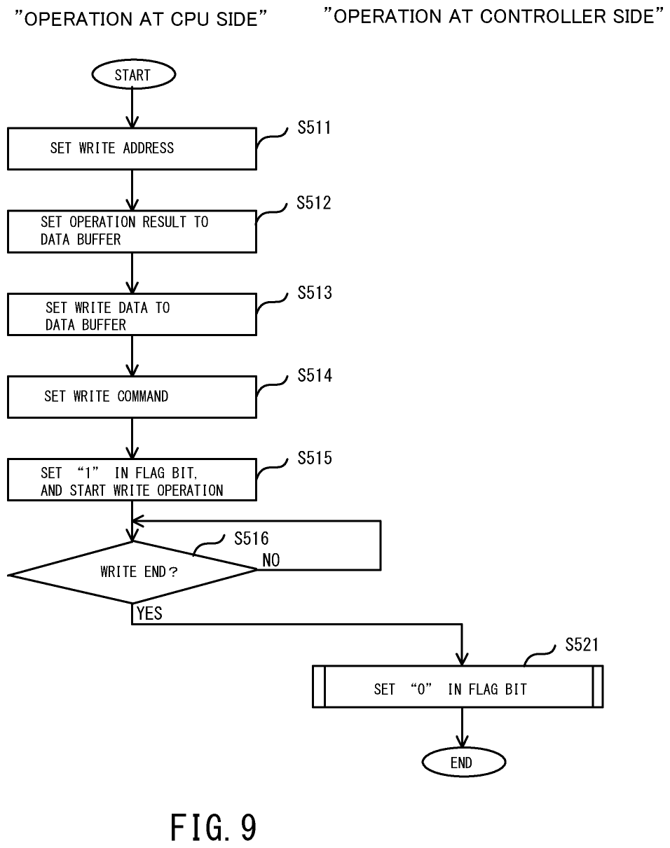

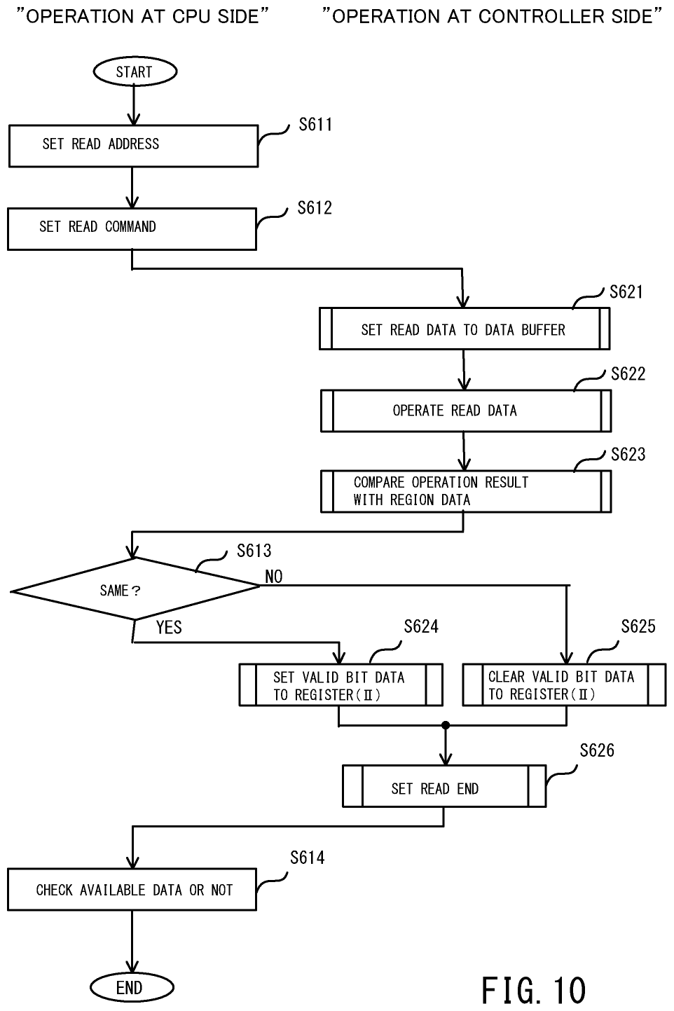

Next, operations of the semiconductor integrated circuit 100a will be described with reference to FIGS. 9 and 10. FIG. 9 is a flowchart that shows a data write operation. FIG. 10 is a flowchart that shows a data read operation. In FIGS. 9 and 10, operations at a CPU side are shown on the left while operations at a controller side are shown on the right.

As shown in FIG. 9, in the data write operation, the CPU 2 sets a write address to the write read address 26 (step S511). Next, in response to the command from the CPU 2, the error code detection circuit 24 (CRC) calculates write data, and the CPU 2 sets the calculation result to the error code result storage region 31 in the data buffer 23a (step S512).

Subsequently, the CPU 2 sets the write data to the data storage region 32 in the data buffer 23a (step S513). Next, the CPU 2 sets a data write command to the register (I) 21 (step S514).

Subsequently, the CPU 2 sets “1” in the flag bit of the register (I) 21 and starts writing the data to a specified memory region (step S515).

Next, the CPU 2 determines whether the data writing ends (step S516). When the data writing to the memory region 10a does not end yet, the information in the flag bit of the register (I) remains as “1.” When the writing to the memory region 10a ends, the controller 20a sets “0” in the flag bit of the register (I) 21 (step S521).

As shown in FIG. 10, in the data read operation, the CPU 2 sets a read address to the write read address 26 (step S611). Next, the CPU 2 sets a data read command to the register (I) 21 (step S612).

Subsequently, the controller 20a forwards and sets the data from the specified memory region to the data buffer 23a (step S621). Next, the controller 20a calculates the forwarded error code detection of the memory region using the error code detection circuit 24 (CRC) (step S622). Subsequently, the controller 20a compares the CRC calculation result with region data of the error code result storage region 31 (step S623).

Next, the CPU 2 determines whether the CRC calculation result and the region data of the error code result storage region 31 are the same (step S613). When the CRC calculation result and. the region data of the error code result storage region 31 are the same, the controller 20a sets a valid hit to the register (II) 22 (step S624). When the CRC calculation result and the region data of the error code result storage region 31 are different, the controller 20a clears the valid bit from the register (II) 22 (step S625).

Subsequently, the controller 20a sets ending of the data reading (step S626). Next, after ending the data reading, the CPU 2 checks the valid bit, and when the data is available, the CPU 2 reads the data from the data buffer 23a (step S614).

In the second embodiment, when the power is interrupted or shut down during the data write operation, the data of the error code result storage region and the data of the data storage region are not matched. Thus, it is possible to determine whether the written data is available data.

As described above, the semiconductor integrated circuit 100a of the second embodiment is provided with the nonvolatile semiconductor memory device 1a, the CPU 2, and the volatile semiconductor memory device 3. The nonvolatile semiconductor memory device la includes the memory region 10a and the controller 20a. The memory region 10a includes the data storage region 11 and the error code result storage region 13. The controller 20a includes the register (I) 21 (first register), the register (II) 22 (second register), the data buffer 23a, the error code detection circuit 24, and the write read address 26. In the data buffer 23a, the error code result storage region 31 having a capacity of 1 byte same as the capacity of the error code result storage region 13 in the memory region 10a and the data storage region 32 having a capacity of 16 bytes same as the capacity of the data storage region 11 in the memory region 1.0a are paired with each other, and. a plurality of stages of memory regions are provided like the memory region 10a. The CRC is used for the error code detection circuit 24, and the error code detection circuit 24 detects an error code.

Thus, it is possible to use a simple configuration to determine whether the data written to the nonvolatile semiconductor memory device is available. In the semiconductor integrated circuit 100a of the second embodiment, no dedicated software is required to determine whether the data written to the nonvolatile semiconductor memory device is available.

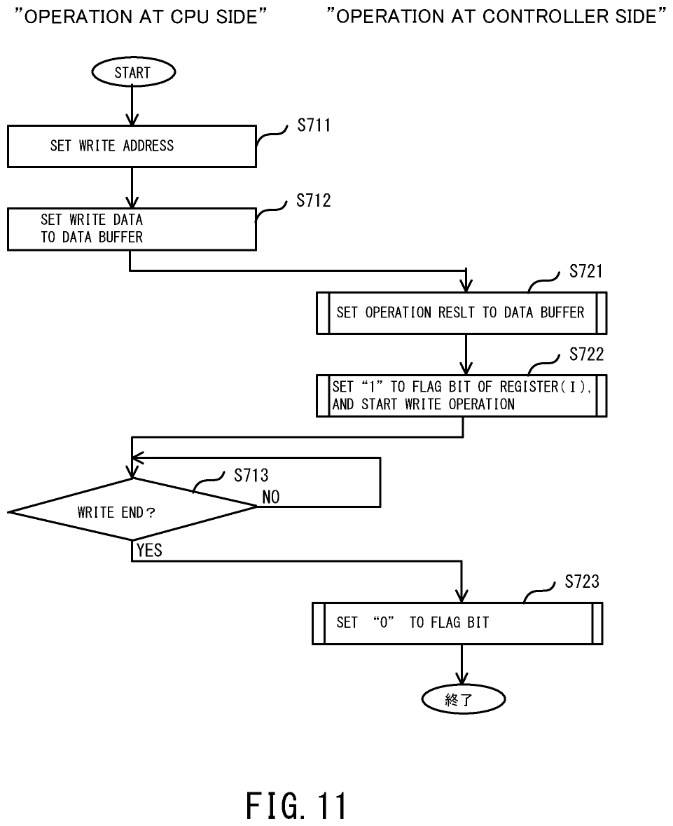

Operations of a semiconductor integrated circuit according to a third embodiment will be described with reference to the drawings. FIG. 11 is a flowchart that shows a data write operation. In FIG. 11, operations at a CPU side are shown on the left while operations at a controller side are shown on the right.

The semiconductor integrated circuit (not illustrated) according to the third embodiment has a similar configuration as the configuration of the semiconductor integrated circuit 100a of the second embodiment. The data write operation of the third embodiment is a modification of the data write operation of the second embodiment. Note that, the data read operation is similar to the data read operation of the second embodiment (see FIG. 10), and thus the description is omitted.

As shown in FIG. 11, in the data write operation, the CPU 2 sets a write address to the write read address 26 (step S711). Next, the CPU 2 sets write data to the data buffer 23a. In this process, information of the error code detection result is not set (step S712).

Subsequently, the controller 20a sets a calculation result, which is obtained by calculation of the write data executed by the error code detection circuit 24 (CRC), to the error code result storage region 31 of the data buffer 23a (step S721). Next, the controller 20a sets “1” in the flag bit of the register (I) 21 and starts writing the data to the specified memory region (step S722).

Subsequently, the CPU 2 determines whether the data writing ends (step S713). When the data writing to the memory region 10a does not end yet, the information in the flag bit of the register (I) 21 remains as “1.” When the writing to the memory region 10a ends, the controller 20a sets “0” in the flag bit of the register (I) 21 (step S723).

In the semiconductor integrated circuit of the third embodiment, the error code detection by the CPU 2 is omitted.

As described above, in the data write operation of the semiconductor integrated circuit of the third embodiment, the error code detection is executed by the controller 20a.

Thus, it is possible to use a simple configuration to determine whether the data written to the nonvolatile semiconductor memory device is available. In addition, loads on the CPU 2 are further reduced than the second embodiment, and this makes it possible to shorten the time of data writing.

While certain embodiments have been described, these embodiments have been presented by way of example only; and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and. their equivalents are intended to cover such forms or modifications as would fall within the scope and spirit of the inventions.

What is claimed is:

1. A semiconductor integrated circuit, comprising:
a nonvolatile semiconductor memory device including a memory region formed of a data storage region to store data and a flag region in which a first value is set when data writing to the data storage region starts and a second value is set when data writing to the data storage region ends, and a controller including an error code detection circuit to detect an error code; and
an integral control processing device configured to integrally control an overall system by exchanging various kinds of signals and data with the controller.

2. The semiconductor integrated circuit according to claim 1, wherein
when reading data stored in the data storage region, the integral control processing device determines that the data read from the data storage region is unavailable when information stored in the flag region is the first value and determines that the data read from the data storage region is available when information stored in the flag region is the second value.

3. The semiconductor integrated circuit according to claim 1, wherein
the flag region is a flag bit having 1 bit.

4. The semiconductor integrated circuit according to claim 3, wherein
the first value is “1” and the second value is “0.”

5. The semiconductor integrated circuit according to claim 1, wherein
based on a command from the integral control processing device, the controller executes writing of data to the memory region and reading data stored in the memory region.

6. The semiconductor integrated circuit according to claim 1, wherein
the controller further includes a first register, a second register, and a data buffer, wherein
the first register sets a write command to the memory region in response to a command from the integral control processing device,
the second register temporarily stores a result written in the memory region and transmits the written result to the integral control processing device, and
the data buffer temporarily stores data to be written to the memory region and data read from the memory region.

7. The semiconductor integrated circuit according to claim 1, wherein
any one of a NAND flash memory, a resistive random access memory (ROAM), a magnetoresistive random access memory (MRAM), a phase change random access memory (PRAM), and a ferroelectric random access memory (FeRAM) is used as the nonvolatile semiconductor memory device.

8. The semiconductor integrated circuit according to claim 1, wherein
any one of a central processing unit (CPU), a processor, and a micro processing unit (MPU) is used as the integral control processing device.

9. A semiconductor integrated circuit, comprising:
a nonvolatile semiconductor memory device including
a memory region formed of a first data storage region to store data and a first error code result storage region to which a detection result from detection of an error code in write data to be written to the first data storage region is set, and
a controller including
a data buffer including a second data storage region having the same capacity as a capacity of the first data storage region and a second error code result storage region having the same capacity as a capacity of the first error code result storage region, and
an error code detection circuit configured to detect an error code; and
an integral control processing device to integrally control an overall. system by exchanging various kinds of signals and data with the controller.

10. The semiconductor integrated circuit according to claim 9, wherein
the controller includes a first register to set a data write command of the integral control processing device, and
the integral control processing device starts data writing to the first data storage region after setting “1” in a flag bit of the first register and sets “0” in the flag bit of the first register when the data writing to the first data storage region ends.

11. The semiconductor integrated circuit according to claim 10, wherein
when reading data stored in the first data storage region,
the controller sets the read data by forwarding the data to the data buffer, calculates error code detection of the forwarded data of the memory region with the error code detection circuit, and compares the calculation result with data stored in the first error code result storage region, and
the integral control. processing device determines whether the calculation result and the data stored in the first error code result storage region are the same.

12. The semiconductor integrated circuit according to claim 9, wherein
based on a command from the integral control processing device, the controller executes writing of data to the memory region and reading of data stored in the memory region.

13. The semiconductor integrated circuit according to claim 9, wherein
the controller further includes a second register and a write read address, wherein
the second register temporarily stores a result written to the memory region and transmits the written result to the integral control processing device, and
the write read. address obtains a write address and a read address from the integral control processing device.

14. The semiconductor integrated circuit according to claim 9, wherein
any one of a NAND flash memory, a ReRAM, an MRAM, a PRAM, and a FeRAM is used as the nonvolatile semiconductor memory device.

15. The semiconductor integrated circuit according to claim 9, wherein
any one of a central processing unit (CPU), a processor, and a micro processing unit (MPU) is used as the integral control processing device.
